(19) United States
(12) Patent Application Publication
(10) Pub. No.: US 2015/0303907 A1
(43) Pub. Date: Oct. 22, 2015

(54) CM CLAMPING METHODS AND CIRCUITS FOR WIRED COMMUNICATION APPLICATIONS

(71) Applicant: BROADCOM CORPORATION, Irvine, CA (US)

(72) Inventors: Hui PAN, Coto de Caza, CA (US); Yuan Yao, Irvine, CA (US); Ahmad Chini, Mission Viejo, CA (US); Mehmet Vakif Tazebay, Irvine, CA (US); Bruce H. Conway, Aliso Viejo, CA (US)

(73) Assignee: BROADCOM CORPORATION, Irvine, CA (US)

(21) Appl. No.: 14/265,165

(22) Filed: Apr. 29, 2014

Related U.S. Application Data
(60) Provisional application No. 61/980,496, filed on Apr. 16, 2014.

(51) Int. Cl. H03K 5/08; H03H 11/30; H04B 3/16; H03K 5/1252

(52) U.S. Cl. CPC H03K 5/08; H03K 5/1252; H03H 11/30; H04B 3/16; H04L 67/12

(57) ABSTRACT

A device for common mode (CM) clamping in wired communication includes a first circuit and a second circuit. The first circuit is configured to sense a voltage signal across clamp terminals and to generate an output voltage signal based on the sensed voltage signal. The second circuit is configured to compare the output voltage signal with a reference voltage, to generate a pair of current signals based on a result of the comparison, and to provide the pair of current signals to the clamp terminals. The pair of current signals includes a matched pair of CM current signals. The clamp terminals, upon coupling to nodes of a main circuit provide a desired CM impedance between the nodes of the main circuit. The device can be coupled to the main circuit in conjunction with one or more off-chip magnetic components.

### CROSS-REFERENCE TO RELATED APPLICATIONS

This application claims the benefit of priority under 35 U.S.C. §119 from U.S. Provisional Patent Application 61/980,496 filed Apr. 16, 2014, which is incorporated herein by reference in its entirety.

### TECHNICAL FIELD

The present description relates generally to wired communications, and more particularly, but not exclusively, to common mode (CM) clamping methods and circuits for wired communication applications.

### BACKGROUND

In some applications, including automotive applications, the line drivers are expected to be able to tolerate common mode (CM) noise (e.g., a CM surge) to a specific level. The CM surge can result from an electromagnetic interference (EMI). For example, in an automotive application, the line driver has to be able to tolerate, at the output pins, up to 2V of CM surge voltage based on EMI. Accommodation of such a CM signal (e.g., in an automotive chip or in an Ethernet PHY chip for transmission at 100 Mbps or higher speed) can bring about undesirable consequences. For example, higher supply voltage (e.g., at least 3.3 V) is needed which results in higher power consumption. A thick oxide device has to be employed to tolerate the over-voltage stress, which exacerbates speed and power issues. Bulkier and more costly CM chokes (CMCs) or transformers may be needed, which can lead to an increased bill of material (BOM) and potentially differential mode (DM) noise due to a mismatch between mutually coupled inductors.

The above undesirable consequences can become more significant with the data rates scaled by 10× to 1 Gbps for reduced twisted-pair gigabit Ethernet (RTPGE). Therefore, it is highly desirable to clamp at the output pin with a very low (e.g., zero) CM impedance, when the surge occurs, while keeping the DM impedance and the CM termination, at normal common mode noise levels, intact. Existing clamping solutions, although may work for their intended purposes, are facing a number of drawbacks such as limited performance in terms of band-width (BW), capacity, scalability, and flexibility in choice of the CM impedance and operation mode.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates an example of an environment in which common mode (CM) clamping is provided to achieve desired CM impedance in accordance with one or more implementations.

FIGS. 2A and 2B illustrate examples of implementations of a wired communication circuit with a common mode (CM) clamp in accordance with one or more implementations.

FIGS. 3A and 3B illustrate examples of implementations of a CM clamp circuit in accordance with one or more implementations.

FIG. 4 illustrates an example of a method for providing CM clamping for a wired communication circuit in accordance with one or more implementations.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and can be practiced using one or more implementations. In one or more instances, well-known structures and components are shown in block diagram form in order to avoid obscuring the concepts of the subject technology.

The subject technology provides common mode (CM) clamping devices and methods for a number of applications. Examples of the applications include automotive applications, broadband applications with wired connectivity such as Ethernet, and other applications. The disclosed solution allows achieving very low (e.g., close to zero) CM impedance, while keeping the differential mode (DM) impedance and CM termination, at normal noise levels, intact. The subject technology provides a CM clamp circuit that can be independently designed, optimized, and applied to differential nodes, while meeting the CM impedance requirements without affecting DM design and performance. The disclosed CM clamp circuit can be merged with the main circuit, for example, to share an output stage. The subject technology provides a universal solution to CM problems including, but not limited to, CM stability, CM noise rejection, and CM termination. The disclosed clamp circuit can be used with a lower supply voltage (e.g., 1.8 V) and thinner oxide device and provides a higher bandwidth, while achieving significantly higher level electromagnetic compatibility (EMC) and immunity at a lower cost and power consumption.

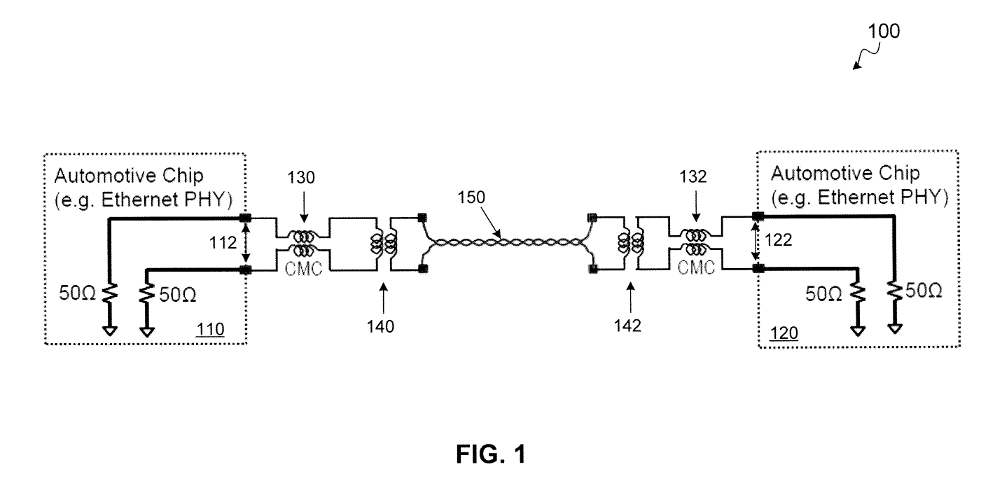

FIG. 1 illustrates an example of an environment 100 in which common mode (CM) clamping is provided to achieve desired CM impedance in accordance with one or more implementations of the subject technology. The environment 100 includes a transmitter circuit 110 (e.g., of an automotive chip, such as Ethernet PHY), a receiver circuit 120 (e.g., of an automotive chip, such as Ethernet PHY) communicating through a wireline 150 (e.g., a single unshielded twisted-pair (UTP) up to 15 meters). The transmitter circuit 110 is coupled to the wireline 150 via a CM choke (CMC) 130 and a transformer 140. The receiver circuit 120 is coupled to the wireline 150 via a CMC 132 and a transformer 142, as shown in FIG. 1. The transmitter circuit 110 and the receiver circuit 120 include termination elements such as 50Ω resistances coupled to their respective output and input ports 112 and 122. For impedance matching, the CMCs 130 and 132 have to provide, at the respective ports 112 and 122, impedances that match the termination elements (e.g., 50Ω resistances).

In some implementations, the CM clamp circuit of the subject technology can be used at various nodes of the transmitter circuit 110 and/or the receiver circuit 120, including the respective output and input ports 112 and 122, and any other nodes such as nodes of the CMCs 130 and 132 and/or nodes of the transformers 140 and 142. In some aspects, the addition of one or more of the disclosed CM clamp circuits to the transmitter circuit 110 and/or the receiver circuit 120 may sufficiently reduce the CM impedance at the desired nodes of the transmitter circuit 110 and/or the receiver circuit 120, such that one or more of the CMCs 130 and 132 and/or the transformers 140 and 142 can be conserved. For data rates up to or higher than 1 Gbps, using reduced twisted pair gigabit Ethernet (RTPGE) for the wireline 150, it is highly desirable to clamp at the output and input ports 112 and 122 with nearly zero CM impedance, when a CM surge such as an electromagnetic interference (EMI) occurs, for example, over the wireline 150. The nearly zero CM impedance has to be provided while keeping the termination at normal CM noise and differential mode impedance intact.

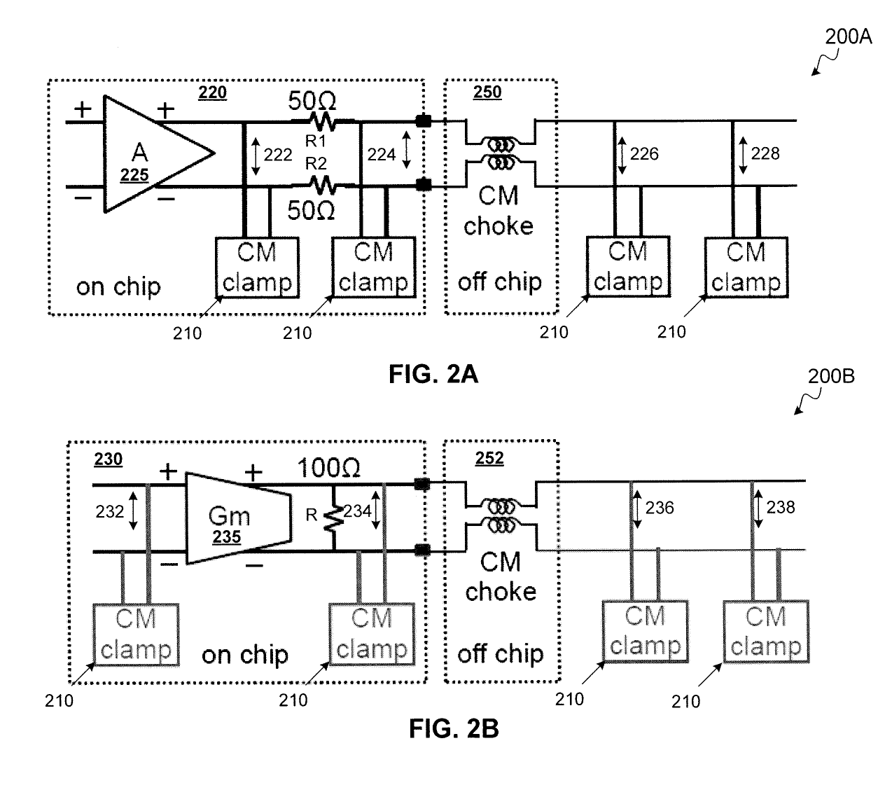

FIGS. 2A and 2B illustrate examples of implementations 200A and 200B of a wired communication circuit with a common mode (CM) clamp in accordance with one or more implementations of the subject technology. In the implementation 200A, a circuit (e.g., a chip) 220 is coupled at an output port (e.g., nodes) 224, via an off-chip CM choke 250 to a wireline (not shown in FIG. 2A for simplicity). In some implementations, the circuit 220 includes a voltage-mode driver circuit 225 coupled through termination resistors R1 and R2 (e.g., with 50Ω resistances) to the output port 224. The CM rejection in the implementation 200A can be provided by coupling one or more CM clamp circuits 210 (e.g., CM clamp devices) on chip 220 or off the chip. In some aspects, the CM clamp circuits 210 can be coupled to nodes 222, 224, 226, and/or 228. The CM clamp circuits 210 can be employed at other nodes of the chip 220 or off the chip with or without the off-chip CM choke 250.

In the implementation 200B, a circuit (e.g., a chip) 230 is coupled at an output port (e.g., nodes) 234, via an off-chip CM choke 252 to a wireline (not shown in FIG. 2B for simplicity). In some aspects, the circuit 230 includes a current-mode driver circuit 235 coupled through a termination resistor R (e.g., with a 100Ω resistance) to the output port 234. The CM rejection in the implementation 200B can be provided by coupling one or more CM clamp circuits 210 on chip 230 or off the chip. In some aspects, the CM clamp circuits 210 can be coupled to nodes 232, 234, 236, and/or 238. The CM clamp circuits 210 can be employed at other nodes of the chip 230 or off the chip with or without the off-chip CM choke 252. The CM clamp circuits 210, as described in more details herein, can be the same or each can be configured to operate in a different mode of operation or to provide a different CM impedance. In some implementations, the CM clamp device can provide the desired CM impedance without the use of any off-chip magnetic components (e.g., CM chokes 250 or 252).

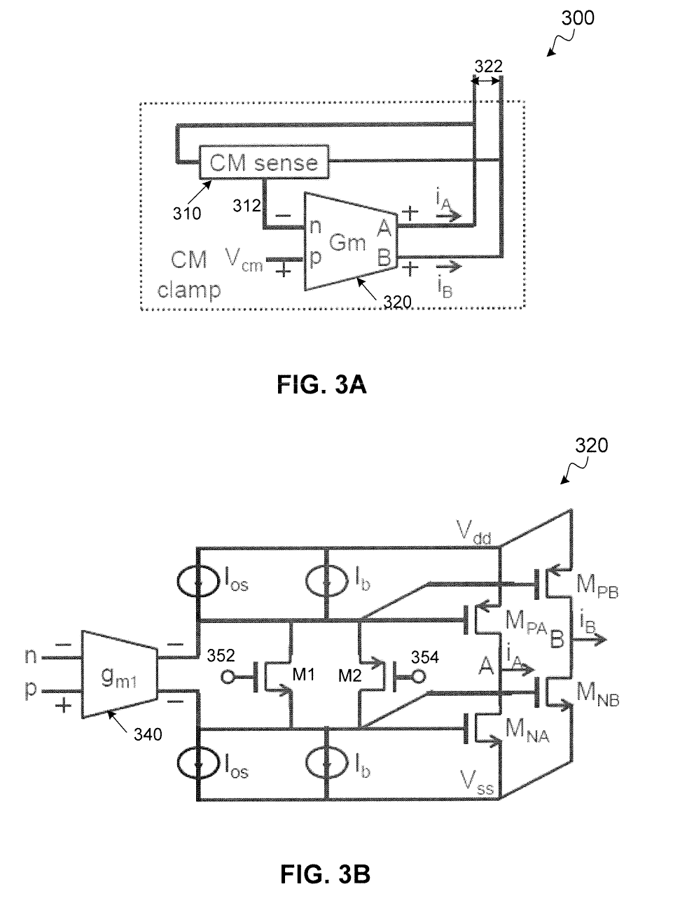

FIGS. 3A and 3B illustrate examples of implementations 300 and 320 of a CM clamp circuit in accordance with one or more implementations of the subject technology. The CM clamp circuit 300 is a stand-alone CM clamp circuit and includes a first circuit 310 (e.g., a CM sense circuit) and a second circuit 320 (e.g., a transconductance circuit). The first circuit 310 senses a voltage signal across clamp terminals 322 and generates an output voltage 312 based on the sensed voltage signal. In some aspects, the first circuit 310 includes one or more resistors and/or capacitors. The second circuit 320 compares the output voltage signal 312 with a reference voltage Vcm and generates a pair of current signals i_{A} and i_{B} based on a result of the comparison. The pair of current signals i_{A} and i_{B} are provided to the clamp terminals 322. The pair of current signals i_{A} and i_{B} are a matched (e.g., identical) pair of CM current signals that can provide a desired CM impedance between nodes of a main circuit (e.g., 220 or 230 of FIG. 2A or 2B), when the clamp terminals 322 are coupled to the nodes of the main circuit. In some aspects, the provision of the matched pair of current signals i_{A} and i_{B} does not affect the differential mode (DM) characteristics of the main circuit.

The second circuit 320 is a DM-in-CM-out transconductance circuit (e.g., with a transconductance Gm) that can reject the DM input by the CM voltage sense and the matched pair of current signals i_{A}=i_{B}=Gm (Vp−Vn), where Vp and Vn, are voltages at respective input nodes p and n of the transconductance circuit 320. In other words, the matched pair of current signals i_{A} and i_{B} are only provided when the output voltage 312 of the CM sense circuit 310 is different from the reference voltage Vcm. In some aspects, the CM sense circuit 310 is configured to provide an output voltage 312 equal to Vcm, when only a differential voltage is sensed at the clamp terminals 322. In practice, the reference voltage Vcm can be set to a desired value based on the application.

In some implementations, the CM clamp circuit 300 is configurable to operate in one or more of a number of modes of operations including class A, class AB, class B, or class C modes of operation. The CM clamp circuit 300 is also configurable to provide the desired CM impedance for multiple levels of CM noise (e.g., EMI).

In one or more implementations, the second circuit 320 (e.g., the DM-in-CM-out transconductance circuit) includes an input stage and a pair of replicated push-pull output stages. The input stage is formed by a transconductance circuit 340 having a transconductance gₘ₁, which is coupled through a biasing circuit to the push-pull output stages. The biasing circuit is formed by a pair of transistors (e.g., MOS transistors) M1 and M2 and current sources I_{b} coupling the transistors to supply voltages V_{dd} and Vₛₛ. The respective gate nodes 352 and 354 of the transistors M1 and M2 can be coupled to suitable bias voltages.

The replicated push-pull output stages are formed by transistor pairs (e.g., CMOS pairs) M_{PA} and M_{NA}, and M_{PB} and M_{NB}. The second circuit 320 can provide the desired CM impedance that is approximately equal to 1/(2Gm), where Gm is the transconductance of the second circuit 320. The second circuit 320 can operate in one of class A, class B, or class AB modes, and can include a pair of matched offset current sources I_{OS} that can facilitate class B or class C operations. The injection of currents by the offset current sources I_{OS} can be programmable in order to allow setting of the class B or C dead-zone. Operation in class B or C, with a dead zone around Vcm where Gm=0, has the following benefits. First, the output transistors M_{PA}, M_{NA}. M_{PB}, and M_{NB} are off for most of the time when there is no CM noise (e.g., CM surge), which reduces power consumption and loading. Second, the push-up transistors M_{PA} and M_{PB}, and the Pull-down transistors M_{NA} and M_{NB} have more headroom when turned on, therefore can reduce DM conversion. The DM conversion can be reduced to a lowest value by, for example, well matching of the transistors of the replicated push-pull output stages at the layout stage (e.g., in ABAB . . . AB pattern).

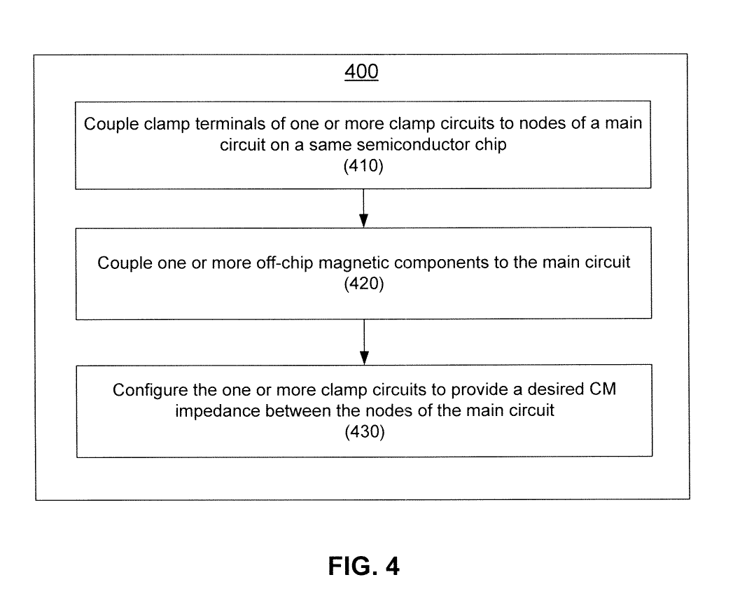

FIG. 4 illustrates an example of a method 400 for providing CM clamping for a wired communication circuit in accordance with one or more implementations of the subject technology. For explanatory purposes, the example method 400 is described herein with reference to, but is not limited to, implementations 200A and 200B of FIGS. 2A and 2B, the CM clamp circuit 300 of FIG. 3A, and the second circuit 320 of FIG. 3B. Further for explanatory purposes, the blocks of the example method 400 are described herein as occurring in serial, or linearly. However, multiple blocks of the example method 400 can occur in parallel. In addition, the blocks of the example method 400 need not be performed in the order shown and/or one or more of the blocks of the example method 400 need not be performed.

In one or more implementations, method 400 includes coupling clamp terminals (e.g., 322 of FIG. 3A) of one or more clamp circuits (e.g., 210 of FIG. 2A or FIG. 2B or 300 of FIG. 3A) to nodes of a main circuit (e.g., 220 of FIG. 2A or 230 of FIG. 2B) on a same semiconductor chip (410), coupling one or more off-chip magnetic components (e.g., 250 of FIG. 2A) to the main circuit (420), and configuring the one or more clamp circuits to provide a desired CM impedance between the nodes (e.g., 222 and or 224 of FIG. 2A) of the main circuit (430). Each clamp circuit includes a first circuit (e.g., 310 of FIG. 3A) and a second circuit (e.g., 320 of FIG. 3A). The first circuit is configured to sense a voltage signal across the clamp terminals (e.g., 322 of FIG. 3A) and to generate an output voltage signal (e.g., 312 of FIG. 3A) based on the sensed voltage signal. The second circuit is configured to compare the output voltage signal with a reference voltage (e.g., Vcm of FIG. 3A), to generate a pair of current signals (e.g., i_{A} and i_{B} of FIG. 3A or FIG. 3B) based on a result of the comparison, and to provide the pair of current signals to the clamp terminals. The pair of current signals includes a matched pair of CM current signals.

Those of skill in the art would appreciate that the various illustrative blocks, modules, elements, components, and methods described herein can be implemented as electronic hardware, computer software, or combinations of both. To illustrate this interchangeability of hardware and software, various illustrative blocks, modules, elements, components, and methods have been described above generally in terms of their functionality. Whether such functionality is implemented as hardware or software depends upon the particular application and design constraints imposed on the overall system. Skilled artisans can implement the described functionality in varying ways for each particular application. Various components and blocks can be arranged differently (e.g., arranged in a different order, or partitioned in a different way) all without departing from the scope of the subject technology.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

A phrase such as “an aspect” does not imply that such aspect is essential to the subject technology or that such aspect applies to all configurations of the subject technology. A disclosure relating to an aspect can apply to all configurations, or one or more configurations. An aspect can provide one or more examples of the disclosure. A phrase such as an “aspect” refers to one or more aspects and vice versa. A phrase such as an “embodiment” does not imply that such embodiment is essential to the subject technology or that such embodiment applies to all configurations of the subject technology. A disclosure relating to an embodiment can apply to all embodiments, or one or more embodiments. An embodiment can provide one or more examples of the disclosure. A phrase such an “embodiment” can refer to one or more embodiments and vice versa. A phrase such as a “configuration” does not imply that such configuration is essential to the subject technology or that such configuration applies to all configurations of the subject technology. A disclosure relating to a configuration can apply to all configurations, or one or more configurations. A configuration can provide one or more examples of the disclosure. A phrase such as a “configuration” can refer to one or more configurations and vice versa.

The word “exemplary” is used herein to mean “serving as an example, instance, or illustration.” Any embodiment described herein as “exemplary” or as an “example” is not necessarily to be construed as preferred or advantageous over other embodiments. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

The previous description is provided to enable any person skilled in the art to practice the various aspects described herein. Various modifications to these aspects will be readily apparent to those skilled in the art, and the generic principles defined herein can be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A device for common mode (CM) clamping in wired communication, the device comprising:
a first circuit configured to sense a voltage signal across clamp terminals and to generate an output voltage signal based on the sensed voltage signal; and
a second circuit configured to:
compare the output voltage signal with a reference voltage;
generate a pair of current signals based on a result of the comparison; and
provide the pair of current signals to the clamp terminals,
wherein:
the pair of current signals comprise a matched pair of CM current signals, and
the clamp terminals, upon coupling to nodes of a main circuit provides a desired CM impedance between the nodes of the main circuit.

2. The device of claim 1, wherein coupling the clamp terminals to the nodes of the main circuit does not affect the differential mode (DM) characteristics of the main circuit.

3. The device of claim 1, wherein the main circuit comprises one of an automotive circuit, a broad-band wired-connectivity circuit, and wherein the device is configurable to be operable in one or more of a number of modes of operations including class A, class AB, class B, or class C modes of operation.

4. The device of claim 3, wherein a combination of multiple versions of the device are configurable to be coupled to same nodes of the main circuit, wherein the multiple versions of the device are configurable to be operable in the one or more modes of operation.

5. The device of claim 1, wherein the device is a stand-alone device, wherein the nodes of a main circuit comprises at least one of input terminals of a receiver or output terminals of a transmitter, wherein the receiver and the transmitter belong to a same communication channel, and wherein the device is configurable to provide the desired CM impedance without off-chip magnetic components.

6. The device of claim 1, wherein the device is configurable to provide the desired CM impedance for multiple levels of electromagnetic interference (EMI), wherein the device is used in conjunction with one or more off-chip magnetic components, and wherein the one or more off-chip magnetic components comprise at least one of transformers or CM chokes.

7. The device of claim 1, wherein the second circuit comprises a DM-in-CM-out transconductance circuit that comprises a pair of replicated push-pull output stages configured to generate the pair of current signals.

8. The device of claim 7, wherein the DM-in-CM-out transconductance circuit is configured to operate in at least one of class A, or class AB, wherein the DM-in-CM-out transconductance circuit further comprises a pair of matched offset current sources and is configured to allow class B or class C operation.

9. The device of claim 7, wherein the DM-in-CM-out transconductance circuit is configured to provide the desired CM impedance, wherein the desired CM impedance is approximately equal to 1/(2Gm), and wherein Gm is the transconductance of the DM-in-CM-out transconductance circuit.

10. A method for providing common mode (CM) clamping in a wired communication circuit, the method comprising:
coupling clamp terminals of one or more clamp circuits to nodes of a main circuit on a same semiconductor chip;
coupling one or more off-chip magnetic components to the main circuit; and
configuring the one or more clamp circuits to provide a desired CM impedance between the nodes of the main circuit,
wherein each clamp circuit of the one or more clamp circuits comprises:
a first circuit configured to sense a voltage signal across the clamp terminals and to generate an output voltage signal based on the sensed voltage signal; and
a second circuit configured to:
compare the output voltage signal with a reference voltage;
generate a pair of current signals based on a result of the comparison; and
provide the pair of current signals to the clamp terminals,
wherein the pair of current signals comprise a matched pair of CM current signals.

11. The method of claim 10, further comprising configuring the one or more clamp circuits such that coupling the clamp terminals to the nodes of the main circuit does not affect the differential mode (DM) characteristics of the main circuit.

12. The method of claim 10, wherein the main circuit comprises one of an automotive circuit, a broad-band wired-connectivity circuit, and further comprising configuring the one or more clamp circuits to be operable in one or more of a number of modes of operations including class A, class AB, class B, or class C modes of operation.

13. The method of claim 10, wherein each of the one or more clamp circuits is a stand-alone clamp circuit, wherein the nodes of a main circuit comprises at least one of input terminals of a receiver or output terminals of a transmitter, wherein the receiver and the transmitter belong to a same communication channel, and wherein the device is configurable to provide the desired CM impedance without off-chip magnetic components.

14. The method of claim 10, further comprising configuring the one or more clamp circuits to provide the desired CM impedance for multiple levels of electromagnetic interference (EMI), and wherein the one or more off-chip magnetic components comprise at least one of transformers or CM chokes.

15. The method of claim 10, wherein the second circuit comprises a DM-in-CM-out transconductance circuit that comprises a pair of replicated push-pull output stages configured to generate the pair of current signals.

16. A wired communication circuit with common mode (CM) clamp, the circuit comprising:
one or more clamp circuits coupled to a driver circuit on a same semiconductor chip; and
one or more off-chip magnetic components coupled to the driver circuit,
wherein:
the one or more clamp circuits are configured to provide a desired CM impedance between nodes of the driver circuit coupled to the one or more clamp circuits,
the driver circuit comprises a voltage mode driver circuit including termination elements, and
the one or more clamp circuits are coupled to at least one side of the termination elements.

17. The circuit of claim 16, wherein the driver circuit comprises a current mode driver circuit including a termination element, and the one or more clamp circuits are coupled to at least one of input nodes or output nodes of the current mode driver circuit.

18. The circuit of claim 16, wherein each of the one or more clamp circuits comprises:
a first circuit configured to sense a voltage signal across clamp terminals of the respective clamp circuit to generate an output voltage signal based on the sensed voltage signal; and
a second circuit configured to:
compare the output voltage signal with a reference voltage;
generate a pair of current signals based on a result of the comparison; and
provide the pair of current signals to the clamp terminals,
wherein the pair of current signals comprise a matched pair of CM current signals.

19. The circuit of claim 18, wherein the second circuit comprises a DM-in-CM-out transconductance circuit that comprises a pair of replicated push-pull output stages configured to generate the pair of current signals, and wherein the DM-in-CM-out transconductance circuit is configured to operate in at least one of class A, class B, or class AB.

20. The circuit of claim 18, wherein the DM-in-CM-out transconductance circuit further comprises a pair of matched offset current sources and is configured to allow class B or class C operation, wherein the DM-in-CM-out transconductance circuit is configured to provide the desired CM impedance, wherein the desired CM impedance is approximately equal to 1/(2Gm), and wherein Gm is the transconductance of the DM-in-CM-out transconductance circuit.
